(19) United States
(12) Patent Application Publication
(10) Pub. No.: US 2024/0379764 A1
(43) Pub. Date: Nov. 14, 2024

(54) GATE-ALL-AROUND TRANSISTOR AND METHOD FOR MANUFACTURING THE SAME

(71) Applicant: INSTITUTE OF MICROELECTRONICS, CHINESE ACADEMY OF SCIENCES, Beijing (CN)

(72) Inventors: Yongliang LI, Beijing (CN); Fei ZHAO, Beijing (CN)

(21) Appl. No.: 18/533,891

(22) Filed: Dec. 8, 2023

(30) Foreign Application Priority Data
May 9, 2023 (CN) 202310519529.3

(51) Int. Cl. H01L 29/10; H01L 29/06; H01L 29/423; H01L 29/66; H01L 29/775

(52) U.S. Cl. CPC H01L 29/1083; H01L 29/0673; H01L 29/42392; H01L 29/66439; H01L 29/66545; H01L 29/775

(57) ABSTRACT

A gate-all-around transistor and a method for manufacturing the same. The gate-all-around transistor comprises: a semiconductor substrate; an active structure disposed on the semiconductor substrate, where the active structure comprises a source, a drain, and a channel between the source and the drain; a doped epitaxial structure, where a portion of the semiconductor substrate beneath the channel is recessed to form a first groove, the first groove is fully filled with the doped epitaxial structure, and primary carriers of the doped epitaxial structure are opposite in polarity to primary carriers of the source and the drain; and a gate stack structure surrounding the channel, where a portion of the gate stack structure beneath the channel is disposed between the doped epitaxial structure and the channel.

The present application claims priority to Chinese Patent Application No. 202310519529.3, titled “GATE-ALL-AROUND TRANSISTOR METHOD FOR MANUFACTURING THE SAME,” filed on May 9, 2023 with the China National Intellectual Property Agency, which is incorporated herein by reference in its entirety.

### FIELD

The present disclosure relates to the technical field of semiconductors, and in particular to a gate-all-around transistor and a method for manufacturing the gate-all-around transistor.

### BACKGROUND

Gate-all-around (GAA) transistors emerge with development of semiconductor technology. In the gate-all-around transistors, a gate stack structure is formed not only over a channel and on sidewalls of the channel, but also beneath the channel. Hence, in comparison with planar transistors and fin field-effect transistors, the GAA transistors have a better control on the channel and have a better performance in suppressing the short channel effect.

Although capable of suppressing parasitic channel leakage, conventional methods for manufacturing GAA transistors are subject to problems such as reduction in operation performances and difficulties in integration of the GAA transistors.

### SUMMARY

A gate-all-around (GAA) transistor and a method for manufacturing the GAA transistor are provided according to embodiments of the present disclosure. Inter-band tunneling is avoided while effectively suppressing parasitic channel leakage of the GAA transistor, which improves an operating performance of the GAA transistor. Moreover, manufacturing of the GAA transistor is less complicated.

In a first aspect, a GAA transistor is provided according to embodiments of the present disclosure. The GAA transistor comprises a semiconductor substrate, an active structure, a doped epitaxial structure, and a gate stack structure. The active structure is disposed on the semiconductor substrate, and comprises a source, a drain, and a channel between the source and the drain. A portion of the semiconductor substrate beneath the channel is recessed to form a first groove, and the first groove is fully filled with the doped epitaxial structure. Primary carriers of the doped epitaxial structure are opposite in polarity to primary carriers of the source and the drain. The gate stack structure surrounds the channel, and a portion of the gate stack structure beneath the channel is disposed between the doped epitaxial structure and the channel.

In the foregoing structure, the semiconductor substrate is recessed to form the first groove at the portion beneath the channel, the first groove is fully filled with the doped epitaxial structure, and the primary carriers of the doped epitaxial structure are opposite in polarity to the primary carriers of the source and the drain. Moreover, the gate stack structure surrounds the channel, and the portion of the gate stack structure beneath the channel is disposed between the doped epitaxial structure and the channel. Thereby, during operation of the GAA transistor, the doped epitaxial structure is capable to suppress parasitic channel leakage due to reverse-biased PN junctions formed with the source and the drain, respectively. Further, the doped epitaxial structure has a greater doping concentration, which improves an effect of suppressing the parasitic channel leakage. The doped epitaxial structure, although filling the first groove beneath the channel, is not disposed beneath the source and the drain. Thereby, the source and the drain are formed the semiconductor substrate having smaller doping concentration than the doped epitaxial structure, which prevents inter-band tunneling at the source and the drain.

In conventional technology, a highly doped layer is formed below a source, a drain, and a channel through halo implantation to improve an effect of suppressing parasitic channel leakage, which induces a problem of inter-band tunneling. It can be seen that he GAA transistor provided herein is free of such problem.

Moreover, in the GAA transistor provided herein, a heavily doped epitaxial material (which is for fabricating the doped epitaxial structure) may be formed at least at the portion of the semiconductor substrate beneath the channel through conventional semiconductor processing such as etching and epitaxy, before the active structure is formed, which is sufficient to suppress parasitic channel leakage and prevent inter-band tunneling. It is not necessary to form an isolation layer between the active structure and the semiconductor substrate through complicated dielectric isolation techniques. Hence, integration of the GAA transistor is less difficult, which improves a yield of the GAA transistors.

In a second aspect, a method for manufacturing a GAA transistor is provided according to an embodiment of the present disclosure. The method comprises: providing a semiconductor substrate; inlaying a doped epitaxial structure in the semiconductor substrate, where a surface of the doped epitaxial structure is flush with a surface of the semiconductor substrate; forming an active structure at the surface of the semiconductor substrate, where the active structure comprises a source, a drain, and a channel between the source and the drain, and the doped epitaxial structure is disposed beneath the channel and not beneath the source and the drain; forming a gate stack structure surrounding the channel, where a portion of the gate stack structure beneath the channel is disposed between the doped epitaxial structure and the channel.

Beneficial effects of the second aspect and various embodiments thereof may refer to the beneficial effects of the first aspect and various embodiments thereof, and are not repeated herein.

### BRIEF DESCRIPTION OF THE DRAWINGS

Drawings described herein are intended for facilitating further understanding of the present disclosure, and constitute a part of the present disclosure. Illustrative embodiments of the present disclosure and corresponding description are intended for explaining the present disclosure, and shall not be construed as improper limitations on the present disclosure.

FIGS. 1 to 16 are schematic structural diagrams during a process of manufacturing a gate-all-around transistor according to embodiments of the present disclosure.

Numeral references:

| | |
|---|---|
| 11: semiconductor substrate, | 12: second groove, |
| 13: doped epitaxial material, | 14: sacrificial layer, |
| 15: channel layer, | 16: fin, |
| 17: doped epitaxial structure, | 18: shallow trench isolation, |
| 19: fin-shaped structure, | 20: sacrificial gate, |
| 21: gate sidewall, | 22: source, |
| 23: drain, | 24: dielectric layer, |
| 25: channel, | 26: gate stack structure. |

### DETAILED DESCRIPTION OF EMBODIMENTS

Hereinafter embodiments of the present disclosure will be described with reference to the drawings. It should be understood that the description are only exemplary and are not intended for limiting the scope of the present disclosure. Furthermore, hereinafter description on well-known structures and techniques are omitted to avoid unnecessarily confusion on concepts of the present disclosure.

Various structural schematic diagrams for embodiments of the present disclosure are shown in the drawings. The drawings are not drawn to scale, and some details may be enlarged while some details may have been omitted for conciseness. Shapes, relative dimensions, and relative positions of various regions and layers shown in the figures are only exemplary. In practice, there may be deviations due to manufacturing tolerances or technical limitations. Those skilled in the art may design a region or a layer having a different shape, dimension, or position according to an actual requirement.

Herein when a layer/element is defined as being “on” another layer/element, it may be disposed directly on the other layer/element, or there may be intervening layers/elements between the two. In addition, in a case that one layer/element is “over/above” another layer/element in one orientation, such layer/element may be “under/beneath” the other layer/element in an reversed orientation. In order to clarify addressed technical issues, technical solutions, and beneficial effects of the present disclosure, the present disclosure will be further described in detail below with reference to the drawings and embodiments. It should be understood that specific embodiments described herein are only intended for explaining the present disclosure rather than limiting the present disclosure.

In addition, terms such as “first” and “second” are for descriptive purposes and shall not be construed as indicating explicitly or implicitly relative importance among or a quantity of concerning technical features. That is, a subject modified by “first” or “second” may indicate one or more of such subjects. Unless explicitly indicated otherwise, herein the term “multiple” refers to two or more, and the term “some” refers to one or more.

Unless otherwise clearly stated and limited, herein the terms “mounted”, “connected” and “interconnected” shall be understood in a broad sense. For example, they may refer to fixed connection, detachable connection, or integral connection, may refer to mechanical connection or electrical connection, may refer to direct connection or indirect connection via an intermediate medium, and may refer to internal connection between two elements or interaction between two elements. Those skilled in the art may appreciate specific meaning of the above terms according to specific context.

Gate-all-around (GAA) transistors emerge with development of semiconductor technology. In the gate-all-around transistors, a gate stack structure is formed not only over a channel and on sidewalls of the channel, but also beneath the channel. Hence, in comparison with planar transistors and fin field-effect transistors, the GAA transistors have a better control on the channel, have a stronger capability of suppressing the short channel effect, and thus have better operation performances.

Although capable of suppressing parasitic channel leakage, conventional methods for manufacturing GAA transistors are subject to problems such as reduction in operation performances and difficulties in integration of the GAA transistors. Specifically, the conventional method usually adopts two manners for suppressing parasitic channel leakage in GAA transistors.

A first manner is as follows. At least one period of stacked layers is formed on a substrate, and each period of stacked layers comprises a sacrificial layer and a channel layer which is on the sacrificial layer. The stacked layers are etched downward until exposing a part of the substrate, so as to form a fin. Afterwards, shallow trench isolation is formed on the portion of the substrate not covered by the fin, and then impurity ions having opposite polarity to the majority carriers of the GAA transistor are implanted into the fin through halo implantation, so as to form highly doped layer(s) at a middle part and a lower part (the substrate which is a part of the fin and exposed by etching). Thereby, the highly doped layer(s) located beneath the channel would form reverse-biased PN junctions with a source and a drain, respectively, which are formed in subsequent processing, which suppresses leakage due to a parasitic channel.

A second manner is as follows. A to-be-oxidized layer is formed before the at least one period stacked layer is formed on the substrate. Hence, after the fin is fabricated through etching, a part of the to-be-oxidized layer remains between the fin and the substrate. Afterwards, the to-be-oxidized layer is oxidized to form an isolation layer through selective oxidation before the source and the drain are formed. Thereby, after an active structure comprising the source, the drain, and the channel is formed, the active structure is isolated from the substrate via the isolation layer, which suppresses leakage due to a parasitic channel.

The first manner utilizes the halo implantation to suppress the leakage. As long as being within a certain range, the greater a concentration of dopants in the highly doped layer is, the better an effect of suppressing the parasitic channel leakage is. Since the highly doped layer is not only located beneath the channel but also beneath the source and the drain, increasing the concentration of dopants in the highly doped layer would enhance inter-band tunneling in the source and the drain, and thus result in a reduction in operating performances of the GAA transistor. The second manner utilizes dielectric isolation to suppress the leakage. An operation process of, for example, the selective oxidation on the to-be-oxidized layer is too complicated, which render integration of the GAA transistor more difficult.

A GAA transistor and a method for manufacturing the same are provided according to embodiments of the present disclosure, and thereby the foregoing technical issues can be addressed. In the GAA transistor provided herein, a portion of a semiconductor substrate disposed beneath a channel is recessed to form a first groove, and the first groove is fully filled with a doped epitaxial structure. Moreover, primary carriers of the doped epitaxial structure are opposite in polarity to primary carriers of the source and the drain. Thereby, parasitic channel leakage is effectively suppressed while avoiding inter-band tunneling, and the GAA transistor can be manufactured with less difficulties.

Reference is made to FIG. 16. In an embodiment, a GAA transistor comprises a semiconductor substrate 11, an active structure, a doped epitaxial structure 17, and a gate stack structure 26. The active structure is disposed on the semiconductor substrate 11. The active structure comprises a source 22, a drain 23, and a channel 25 disposed between the source 22 and the drain 23. A portion of the semiconductor substrate 11 disposed beneath the channel 25 is recessed to form a first groove (not depicted). The first groove is filled with the doped epitaxial structure 17 (which may be heavily doped). Primary carriers of the doped epitaxial structure 17 are opposite in polarity to primary carriers of the source 22 and the drain 23. The channel 25 is surrounded by the gate stack structure 26. A portion of the gate stack structure 26 disposed beneath the channel 25 is formed between the doped epitaxial structure 17 and the channel 25.

A specific structure of the semiconductor substrate may be configured according to an actual application scenario, and is not specifically limited herein. For example, as shown in FIG. 16, the semiconductor substrate 11 may be a silicon substrate, a silicon germanium substrate, a germanium substrate, or another semiconductor substrate, on which no structure has been fabricated.

Alternatively, the semiconductor substrate may be provided with some readily fabricated structure. For example, the GAA transistor is in the second bottommost, or even higher, structural layer of a semiconductor device, and the semiconductor substrate comprises a semiconductor structure located beneath the GAA transistor.

In a material perspective, the source, the drain, and the channel in the active structure may be made of a semiconductor material, such as silicon, silicon germanium, or germanium.

In a structural perspective, the channel may comprise at least one nanostructure, each of which is spaced from the semiconductor substrate by a gap. In a case that the channel comprises at least two nanostructures, different nanostructures may be spaced apart along a lengthwise direction of the gate stack structure, or may be spaced apart along a thickness direction of the semiconductor substrate 11 as shown in FIG. 16.

The first groove is provided for accommodating the doped epitaxial structure at the portion of the semiconductor substrate disposed beneath the channel. As shown in FIG. 16, the first groove is fully filled with the doped epitaxial structure 17, and the primary carriers of the doped epitaxial structure 17 is opposite in polarity to those of the source 22 and the drain 23. Moreover, surrounds the channel 25, and the portion of the gate stack structure 26 disposed beneath the channel 25 is disposed between the doped epitaxial structure 17 and the channel 25. In such case, during operation of the GAA transistor, the doped epitaxial structure 17 can not only suppress parasitic channel leakage through forming reverse-biased PN junctions with the source 22 and the drain 23, respectively, but also have a more significant effect in suppressing parasitic channel leakage due to high doping concentration (i.e., high concentration of dopants) in the doped epitaxial structure 17. In addition, the doped epitaxial structure 17 only fills the first groove under the channel 25, and is not disposed under the source 22 and the drain 23. In this case, the source 22 and the drain 23 are formed on the semiconductor substrate 11 at a portion having small doping concentration, and hence inter-band tunneling is avoided in the source 22 and the drain 23.

On such basis, an effect of the doped epitaxial structure suppressing parasitic channel leakage is determined by spatial coverage of the doped epitaxial structure under the channel, doping concentration of the doped epitaxial structure, and a thickness of the doped epitaxial structure. Therefore, these parameters of the doped epitaxial structure may be determined based on an actual requirement of suppressing parasitic channel leakage in the GAA transistor, and are not specifically limited herein.

The doped epitaxial structure may be disposed beneath only a part of the channel. Alternatively, a shape of a top surface of the doped epitaxial structure may coincide with a projection of the channel on the semiconductor substrate. In comparison, the latter case ensures that the portion of the gate stack structure disposed beneath the channel is only in contact with the doped epitaxial structure, which has the high doping concentration, and not in contact with the semiconductor substrate. Hence, the latter case can suppress the parasitic channel leakage to most extent, which further improves electrical performances of the GAA transistor.

In one embodiment, a thickness of the doped epitaxial structure may range from 10 nm to 40 nm. For example, the thickness of the doped epitaxial structure may be 10 nm, 15 nm, 20 nm, 25 nm, 30 nm, 35 nm, 40 nm, or the like. The thickness within such range can prevent that an effect of suppressing parasitic channel leakage is insignificant due to small thickness of the doped epitaxial structure, which ensures that the GAA transistor have excellent operating performances. Moreover, when the thickness of the doped epitaxial structure has been increased to a certain value, the effect of suppressing parasitic channel leakage would no longer be improved under further increases. Therefore, the thickness within such range can also prevent a waste of materials due to an excessive thickness of the doped epitaxial structure, and reduce difficulty of forming a groove for manufacturing the doped epitaxial structure. Hence, the GAA transistor can be manufactured with reduced costs and less difficulties.

In one embodiment, the doping concentration in the doped epitaxial structure may range from 1×10¹⁸ cm⁻³ to 1×10¹⁹ cm⁻³. For example, the doping concentration in the doped epitaxial structure may be 1×10¹⁸ cm⁻³, 2×10¹⁸ cm⁻³, 4×10¹⁸ cm⁻³, 6×10¹⁸ cm⁻³, 8×10¹⁸ cm⁻³, 1×10¹⁹ cm⁻³, or the like. The doping concentration within such range can prevent that an effect of suppressing parasitic channel leakage is insignificant due to small doping concentration in the doped epitaxial structure, which ensures that the GAA transistor have excellent operating performances. Moreover, when the doping concentration in the doped epitaxial structure has been increased to a certain value, the effect of suppressing parasitic channel leakage would no longer be improved under further increases. Therefore, the doping concentration within such range can also prevent a high manufacturing cost due to excessive doping concentration in the doped epitaxial structure, and reduce difficulty of forming the heavily doped epitaxial structure. Hence, the GAA transistor can be manufactured with reduced costs and less difficulties.

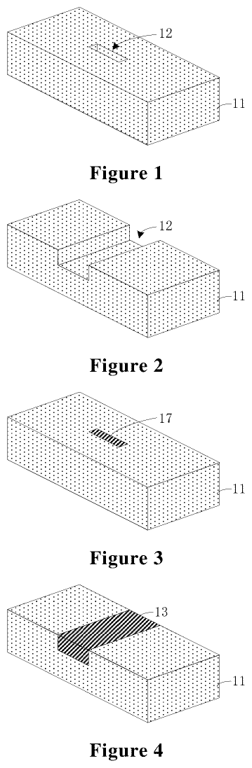

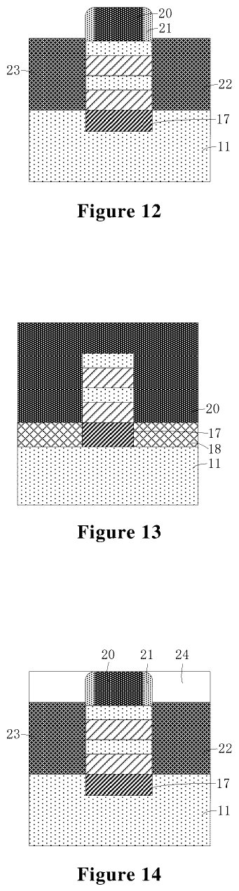

As shown in FIGS. 1 to 15, the doped epitaxial structure 17 is disposed beneath the channel 25, and is formed before the channel 25 is formed. Moreover, the channel 25 in the GAA transistor is generally suspended over the semiconductor substrate 11 through removing the sacrificial layer(s) 14 selectively. Thus, the doped epitaxial structure 17 may be made of a semiconductor material which is different from a material of the sacrificial layer 14, so as to prevent a process of releasing the channel 25 from having a great impact on the doped epitaxial structure 17. Hence, it is ensured that the parasitic channel leakage can be suppressed by the doped epitaxial structure 17.

In one embodiment, a material of a matrix of the doped epitaxial structure may be identical to a material of a matrix of the semiconductor substrate. For example, both the matrix of the semiconductor substrate and the matrix of the doped epitaxial structure are made of silicon. In practice, there is certain etching selectively between a material of the semiconductor substrate and a material of the sacrificial layer, so as to prevent the semiconductor substrate beneath the channel from being etched too much when releasing the channel. Hence, in a case that the matrix of the doped epitaxial structure and (the matrix of) the semiconductor substrate are made of the same material, there is also certain etching selectivity between the material of the doped epitaxial structure and the material of the sacrificial layer, which ensures that an etchant for etching the sacrificial layer would have a great impact on the doped epitaxial structure when releasing the channel.

In one embodiment, the material of the matrix of the doped epitaxial structure may be identical to a material of a matrix of the channel. The beneficial effects of this embodiment may refer to those of the foregoing embodiment in which the matrix of the doped epitaxial structure and the matrix of the semiconductor substrate are made of the same material, and are repeated herein.

Before releasing the channel, the doped epitaxial structure disposed beneath the channel may have a thickness greater than its final thickness, so as to leave a margin for the doped epitaxial structure being etched when releasing the channel. In another embodiment, the material of the matrix of the doped epitaxial structure may be identical to the material of the sacrificial layer, when duration or another parameter of the etching process is controlled to ensure that the etchant for etching the sacrificial layer would not have a great impact on the doped epitaxial structure.

As shown in FIG. 16, the gate stack structure 26 may comprise a gate dielectric layer and a gate which is disposed on the gate dielectric layer. The gate dielectric layer is disposed on a portion of the semiconductor substrate 11 which corresponds to a region for forming the gate, and surrounds the channel 25. A material of the gate dielectric layer may be an insulating material, such as HfO₂, ZrO₂, TiO₂, or Al₂O₃. A material of the gate may be a conductive material, such as TiN, TaN, or TiSiN.

The above solutions can address the problem in conventional technology that a highly doped layer, which is formed below a source, a drain, and a channel through halo implantation to improve an effect of suppressing parasitic channel leakage, induces inter-band tunneling. Moreover, as shown in FIGS. 1 to 7, in the GAA transistor provided herein, the doped epitaxial material 13 (which is heavily doped for fabricating the doped epitaxial structure 17) may be formed at least at the portion of the semiconductor substrate 11 beneath the channel through conventional semiconductor processing such as etching and epitaxy, before the active structure is formed, which is sufficient to suppress parasitic channel leakage and prevent inter-band tunneling. It is not necessary to form an isolation layer between the active structure and the semiconductor substrate through complicated dielectric isolation techniques. Hence, integration of the GAA transistor is less difficult, which improves a yield of the GAA transistors

In some embodiments, the GAA transistor may further comprise at least one of: shallow trench isolation, gate sidewall(s), or a dielectric layer. As shown in FIG. 11, the shallow trench isolation 18 is disposed on the semiconductor substrate 11, and is configured to isolate different active regions on the semiconductor substrate 11, so as to prevent electrical leakage. A thickness of the shallow trench isolation 18 may be configured according to an actual condition. The shallow trench isolation 18 may be made of an insulating material, such as SiN, Si₃N₄, SiO₂, or SiCO. As shown in FIG. 16, the gate sidewalls 21 are formed on two sides of the gate stack structure, and extend along a lengthwise direction of the gate stack structure. The gate sidewall 21 is configured to isolate the gate from other conductive structures formed in subsequent processing, so as to improve electrical stability of the GAA transistor. The dielectric layer 24 covers the semiconductor substrate 11, and a top surface of the dielectric layer 24 is flush with a top surface of the gate stack structure in the GAA transistor. The dielectric layer 24 is configured to protect the source 22 and the drain 23 in the GAA transistor from processing, such as etching and cleaning, when removing a sacrificial gate. Materials of the gate sidewalls 21 and the dielectric layer 24 may be configured according to an actual application scenario, as long as they are applicable to the GAA transistor provided herein.

In a second aspect, a method for manufacturing a GAA transistor is provided according to an embodiment of the present disclosure. Hereinafter a process of manufacturing the GAA transistor is described in conjunction with a cross-sectional view or a stereoscopic view of each structure as shown in FIGS. 1 to 16. In an embodiment, the method for manufacturing the GAA transistor comprises following steps.

First, a semiconductor substrate is provided. Details of the semiconductor substrate may refer to the foregoing embodiments and are not repeated herein.

Then, a doped epitaxial structure 17 is inlaid in the semiconductor substrate 11. Reference is made to FIGS. 3 and 6. A surface of the doped epitaxial structure 17 is flush with a surface of the semiconductor substrate 11.

Details of spatial coverage, thickness, doping concentration, and other parameters of the doped epitaxial structure may refer to the foregoing embodiments and are not repeated herein.

In one embodiment, inlaying the doped epitaxial structure in the semiconductor substrate may comprise following steps.

Reference is made to FIGS. 1 and 2. A second groove 12 may be formed at the surface of the semiconductor substrate 11 through processing such as photolithography and etching.

In an embodiment, a size of the second groove 12 may be equal to a size of the doped epitaxial structure, as shown in FIG. 1. In another embodiment, a width and a depth of the second groove 12 may be equal to a width and a thickness, respectively, of the doped epitaxial structure, and a length of the second groove 12 is greater than a length of the doped epitaxial structure, as shown in FIG. 2. Here a lengthwise direction of the second groove 12 is parallel to a widthwise direction of the gate stack structure, a widthwise direction of the second groove 12 is parallel to a lengthwise direction of the gate stack structure, and a depth-wise direction of the second groove 12 is parallel to a thickness direction of the semiconductor substrate 11.

The width and the depth of the second groove may be equal to the width and the thickness, respectively, of the doped epitaxial structure, and the length of the second groove is greater than the length of the doped epitaxial structure. In such case, when a shape of an opening of the second groove coincides with a projection of the gate stack structure, which is subsequently formed, on the semiconductor substrate, the same mask pattern for fabricating the sacrificial gate and a photoresist which is opposite in polarity to that for fabricating the sacrificial gate may be utilized to form a mask layer for fabricating the second groove may be formed. Thereby, a process for fabricating the doped epitaxial structures is simplified, which reduces manufacturing costs. For example, the sacrificial gate is fabricated by using a positive photoresist. In such case, the same mask pattern for fabricating the sacrificial gate and a negative photoresist may be used to form the mask layer for fabricating the second groove, and then the semiconductor substrate is etched under such mask layer to obtain the second groove.

It is appreciated that when the shape of the opening of the second groove coincides with the projection of the gate stack structure on the semiconductor substrate, another mask may alternatively be utilized for fabricating the second groove. In another embodiment, the second groove and the doped epitaxial structure are fabricated using separate mask patterns, and the length or the width of the second groove may be greater than that of the doped epitaxial structure.

Then, a doped epitaxial material 13 filling the second groove is formed. Reference is made to FIGS. 3 and 4.

In an embodiment, the doped epitaxial material, which fills the second groove fully and covers the surface of the semiconductor substrate, may be formed through epitaxy, and a portion of the doped epitaxial material located outside the second groove is removed through processing such as chemical mechanical polishing, so as to obtain the doped epitaxial material.

As shown in FIGS. 1 and 3, in a case that the size of the second groove 12 is equal to the size of the doped epitaxial structure 17, the doped epitaxial material serves as the doped epitaxial structure 17 directly.

In a case that one or both the width and the length of the second groove is greater than that of the doped epitaxial structure, the formed doped epitaxial material may be patterned under a corresponding mask layer, so as to form the doped epitaxial structure.

Alternative, reference is made to FIGS. 2 and 4. The shape of the opening of the second groove 12 may coincide with the projection of the gate stack structure on the semiconductor substrate 11. In such case, after the second groove 12 is fully filled with the heavily doped epitaxial material 13 and before the heavily doped epitaxial material 13 is patterned, sacrificial layer(s) 14 and channel layer(s) 15 which are alternately stacked may be formed on the surface of the semiconductor substrate 11 through epitaxy along a thickness direction of the semiconductor substrate 11, as shown in FIG. 6. Among the sacrificial layer(s) 14 and the channel layer(s) 15 which are alternately stacked, the bottommost layer is the sacrificial layer 14. Reference is made to FIG. 7. When patterning the doped epitaxial material, the semiconductor substrate 11, the sacrificial layer(s) 14, and the channel layer(s) 15 are also etched to obtain the doped epitaxial structure 17 and a fin-shaped structure 19, which is located above the doped epitaxial structure 17 and a portion of the semiconductor substrate 11.

The channel layer is a layer for fabricating the channel in the GAA transistor. Therefore, a material, a thickness, and a quantity of the channel layer(s) formed on the semiconductor substrate may be determined according to a material of the channel, a thickness of the channel, and a quantity of nanostructure layers in the channel. A portion of the sacrificial layer(s) in a corresponding region may be removed to release a space for forming the gate stack structure. Therefore, a dimension of the sacrificial layer may be determined according to a dimension of the gate stack structure. A quantity of sacrificial layers may be equal to one plus the quantity of channel layers. In such case, the topmost layer among the sacrificial layer(s) and the channel layer(s) which are alternately stacked may also be a sacrificial layer. In such case, the topmost sacrificial layer can protect the topmost channel layer during subsequent etching, which improves quality of the fabricated channel. Alternatively, the quantity of sacrificial layers may be equal to the quantity of channel layers. A material of the sacrificial layer may different from that of the channel layer. For example, the material of the channel layer is silicon, and the material of the sacrificial layer may be silicon germanium.

In the foregoing solution, the shape of the opening of the second groove may coincide with a projection of the gate stack structure on the semiconductor substrate, and the sacrificial layer(s) and channel layer(s) that are alternately stacked may be formed after the heavily doped epitaxial material filling the second groove is formed. In such case, the channel layer(s), the sacrificial layer(s), the doped epitaxial material, and a portion of the semiconductor substrate may be etched by using the same mask layer. It is not necessary to form two or more mask layers for fabricating form the doped epitaxial structure and the fin-shaped structure, which further simplifies the manufacturing process of the GAA transistor. The GAA transistor can be manufacture with lower costs and higher efficiency. In addition, in such case, the fin-shaped structure is located on a protruding portion of the semiconductor substrate which is formed through the etching and on the doped epitaxial structure. On such basis, shallow trench isolation 18 may be formed on the semiconductor substrate 11 through processing such as deposition and epitaxy, after the fin-shaped structure 19 is formed. Reference is made to FIG. 8. The fin-shaped structure 19 is exposed out of the shallow trench isolation 18.

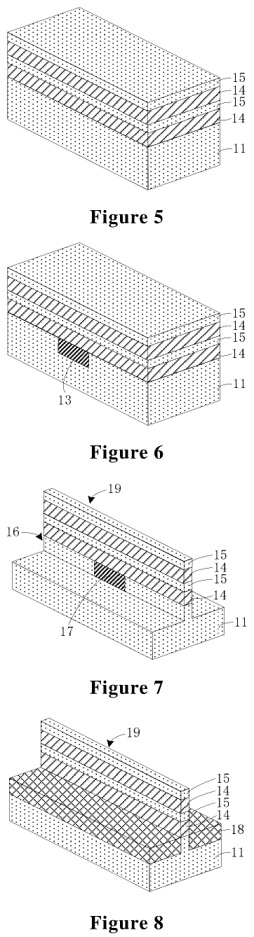

Alternatively, the size of the second groove may be equal to the size of the doped epitaxial structure 17, as shown in FIG. 3, or the doped epitaxial material may be directly patterned by using a corresponding mask layer when one or both of the width and the length of the second groove is greater than that of the doped epitaxial structure. In such cases, the sacrificial layer(s) 14 and the channel layer(s) 15 that are alternately stacked may be formed on the semiconductor substrate 11 and the doped epitaxial structure 17 after the doped epitaxial structure 17 is formed, as shown in FIG. 5. Details of the sacrificial layers 14 and the channel layer(s) 15 may refer to the foregoing embodiment. Then, only the sacrificial layers 14, the channel layer(s) 15, and a part of the semiconductor substrate 11 are etched through processing such as photolithography and etching to form a fin 16, as shown in FIG. 7. Afterwards, the shallow trench isolation 18 may be formed on the semiconductor substrate 11 through processing such as deposition and etching. A top surface of the shallow trench isolation 18 is lower than or is flush with a bottom surface of the bottommost sacrificial layer 14. A portion of the fin which is exposed out of the shallow trench isolation 18 serves as the fin-shaped structure 19.

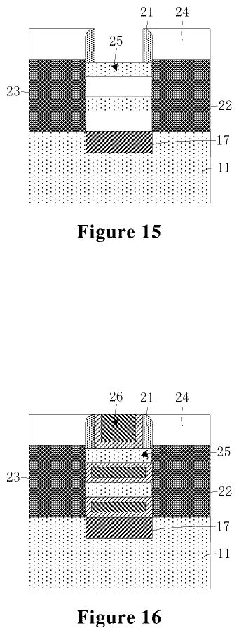

After the doped epitaxial structure and fin-shaped structure are formed, an active structure is formed on the semiconductor substrate 11 at a side on which the doped epitaxial structure 17 has been formed. Reference is made to FIG. 15. The active structure comprises a source 22, a drain 23, and a channel 25 disposed between the source 22 and the drain 23. The doped epitaxial structure 17 is only disposed beneath the channel 25. The materials and other parameters of structures such as the source, the drain, and the channel in the active structure may refer to the foregoing embodiments, and are not repeated herein.

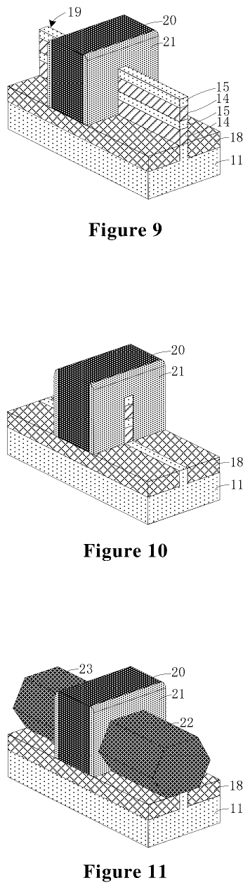

As an example, the fin-shaped structure may comprise a first region, a second region, and a third region arranged along a lengthwise direction of the fin-shaped structure, and the third region is located between the first region and the second region. On such basis, forming the active structure on the semiconductor substrate at the side on which the doped epitaxial structure has been formed comprises following steps. Reference is made to FIG. 9. A sacrificial gate 20 and gate sidewalls 21, which extend across a portion of the fin-shaped structure 19 in the third region, may be formed through processing such as deposition and etching. A material of the sacrificial gate 20 may be polysilicon or another material. The gate sidewalls 21 are disposed at least on two sides of the sacrificial gate 20 along the lengthwise direction. A material of the gate sidewalls 21 may refer to the foregoing embodiment. Then, reference is made to FIG. 10. Portions of the fin-shaped structure in the first region and the second region may be removed through processing such as wet etching or dry etching by using a mask for fabricating the sacrificial gate 20 and the gate sidewall 21. Then, reference is made to FIGS. 11 to 13. The source 22 and the drain 23 may be formed on two sides of the remaining portion of the fin-shaped structure along the lengthwise direction of fin-shaped structure through processing such as epitaxy. Then, reference is made to FIG. 15. The sacrificial gate may be removed through processing such as dry etching or wet etching, and each sacrificial layer in the third region is also removed, such that the channel layer in the third region forms the channel 25.

In some embodiments, the dielectric layer 24 may be formed through processing such as deposition and planarization, after the source and the drain are formed and before the sacrificial gate is removed. Reference is made to FIG. 14. A top surface of the dielectric layer 24 is flush with a top surface of the sacrificial gate 20. A material of the dielectric layer 24 may refer to the foregoing embodiment.

Reference is further made to FIG. 16. A gate stack structure 26 surrounding the channel 25 may be form through processing such as atomic layer deposition, after the active structure is formed. A portion of the gate stack structure 26 disposed beneath the channel 25 is located between the doped epitaxial structure 17 and the channel 25.

It should be noted that the active structure and the gate stack structure may be formed in various manners. How to form the active structure and the gate stack structure may not be a gist of the present disclosure, and hence is briefly introduced herein to facilitate those skilled in the art implementing the present disclosure. Those skilled in the art may utilize another manner for fabricating the active structure and the gate stack structure.

Beneficial effects of the method provided herein and its various implementations may refer to those of the GAA transistor provided herein and its various implementations, and hence are not repeated herein.

Herein technical details of processing such as patterning and etching on each layer may not be illustrated. Those skilled in the art can appreciate that various technical means may be used to form a layer, a region, or the like, which has a desired shape. In addition, those skilled in the art may derive a method which is not exactly identical that illustrated herein for fabricating a same structure. Although each foregoing embodiment is described separately, it does not indicate that the solutions in the various embodiments cannot be used in combination to achieve an advantage.

Hereinabove the embodiments of the present disclosure have been described. The embodiments are only illustrative and are not intended for limiting the scope of the present disclosure. The scope of the disclosure is defined by the appended claims and their equivalents. Those skilled in the art may make various substitutions and modifications without departing from the scope of the present disclosure, and these substitutions and modifications shall fall within the scope of the present disclosure.

1. A gate-all-around (GAA) transistor, comprising:
a semiconductor substrate;
an active structure disposed on the semiconductor substrate, wherein the active structure comprises a source, a drain, and a channel between the source and the drain;
a doped epitaxial structure inlaid in the semiconductor substrate, wherein primary carriers of the doped epitaxial structure are opposite in polarity to primary carriers of the source and the drain, and the doped epitaxial structure is disposed beneath the channel and not beneath the source and the drain; and
a gate stack structure surrounding the channel, wherein a portion of the gate stack structure beneath the channel is disposed between the doped epitaxial structure and the channel.

2. The GAA transistor according to claim 1, wherein a thickness of the doped epitaxial structure ranges from 10 nm to 40 nm.

3. The GAA transistor according to claim 1, wherein a concentration of dopants in the doped epitaxial structure is greater than a concentration of dopants in a portion of the semiconductor substrate in contact with the source and a portion of the semiconductor substrate in contact with the drain.

4. The GAA transistor according to claim 1, wherein a concentration of dopants in the doped epitaxial structure ranges from 1×10¹⁸ cm⁻³ to 1×10¹⁹ cm⁻³.

5. The GAA transistor according to claim 1, wherein a material of a matrix of the doped epitaxial structure is identical to one or both of:
a material of a matrix of the semiconductor substrate, and
a material of the channel.

6. A method for manufacturing a GAA transistor, comprising:
providing a semiconductor substrate;
forming a doped epitaxial structure inlaid in the semiconductor substrate, wherein primary carriers of the doped epitaxial structure are opposite in polarity to primary carriers of the source and the drain;
forming an active structure on the semiconductor substrate, wherein the active structure comprises a source, a drain, and a channel between the source and the drain, and the doped epitaxial structure is disposed beneath the channel and not beneath the source and the drain; and
forming a gate stack structure surrounding the channel, wherein a portion of the gate stack structure beneath the channel is disposed between the doped epitaxial structure and the channel.

7. The method according to claim 6, wherein forming the doped epitaxial structure inlaid in the semiconductor substrate comprises:
forming a groove at the surface of the semiconductor substrate; and
forming a doped epitaxial material which fills the groove fully.

8. The method according to claim 7, wherein a size of the groove is identical to a size of the doped epitaxial structure, and the doped epitaxial material in the groove serves as the doped epitaxial structure.

9. The method according to claim 7, wherein:
a length of the groove is larger than a length of the doped epitaxial structure, or a width of the groove is larger than a width of the doped epitaxial structure, and
after forming the doped epitaxial material which fills the groove fully, the method further comprises:
patterning the doped epitaxial material, wherein the doped epitaxial material remaining after the patterning serves as the doped epitaxial structure.

10. The method according to claim 9, wherein:
after forming the doped epitaxial material which fills the groove fully and before patterning the doped epitaxial material, the method further comprises:
forming at least one sacrificial layer and at least one channel layer, which are alternately stacked on the semiconductor substrate, wherein a bottommost layer among the at least one sacrificial layer and at least one channel layer is one of the at least one sacrificial layer and in contact with the doped epitaxial material; and
patterning the doped epitaxial material comprises:
etching the semiconductor substrate, the at least one sacrificial layer, and the at least one channel layer along with the doped epitaxial material to obtain the doped epitaxial structure and a fin-shaped structure, wherein the fin-shaped structure is disposed on the doped epitaxial structure and a part of the semiconductor substrate.

11. The method according to claim 10, wherein:
the fin-shaped structure comprises a first region, a second region, and a third region located between the first region and the second region, which are arranged along a lengthwise direction of the fin-shaped structure;
forming the active structure on the semiconductor substrate comprises:
forming a sacrificial gate and gate sidewalls, wherein the sacrificial gate and the gate sidewalls each extends across a portion of the fin-shaped structure in the third region, and the gate sidewalls are disposed at least on two sides of the sacrificial gate along the lengthwise direction;
removing another portion of the fin-shaped structure in the first region and the second region after forming the sacrificial gate and the gate sidewalls;
forming the source and the drain on two both sides, respectively, of the fin-shaped structure, which remains after removing the another portion of the fin-shaped structure, along the lengthwise direction;
removing the sacrificial gate after forming the source and the drain; and
removing the at least one sacrificial layer in the third region after the removing the sacrificial gate, wherein the at least one channel layer in the third region serves as the channel.

12. The method according to claim 7, wherein a shape of an opening of the groove coincides with a projection of the gate stack structure on the semiconductor substrate.
